(19) United States
(12) Patent Application Publication
(10) Pub. No.: US 2017/0287743 A1
(43) Pub. Date: Oct. 5, 2017

(54) SUBSTRATE TREATING DEVICE AND SUBSTRATE TREATING METHOD

(71) Applicant: SHIBAURA MECHATRONICS CORPORATION, Yokohama-shi (JP)

(72) Inventors: Nobuo KOBAYASHI, Yokohama-shi (JP); Konosuke SASAHIRA, Yokohama-shi (JP); Katsuhiro YAMAZAKI, Yokohama-shi (JP)

(73) Assignee: SHIBAURA MECHATRONICS CORPORATION, Yokohama-shi (JP)

(21) Appl. No.: 15/474,107

(22) Filed: Mar. 30, 2017

(30) Foreign Application Priority Data
Mar. 31, 2016 (JP) 2016-073352
Mar. 3, 2017 (JP) 2017-040452

(51) Int. Cl. H01L 21/67; H01L 21/02; B08B 3/02; H01L 21/687; B08B 3/04; B08B 3/08

(52) U.S. Cl. CPC H01L 21/67051; B08B 3/041; B08B 3/08; B08B 3/022; H01L 21/68764; H01L 21/02052

(57) ABSTRACT

According to the embodiment, a substrate treating device 1 that rotates and washes a substrate, the device includes a spinning holding mechanism for holding a substrate, a treatment liquid supply nozzle for supplying a treatment liquid to the substrate, a shielding plate that is arranged opposite to the substrate held by the spinning holding mechanism and that moves in a contact/separate direction with respect to the substrate, a shielding plate rotating mechanism for rotating the shielding plate, and a control device for controlling the shielding plate rotating mechanism to rotate the shielding plate without moving the shielding plate from a standby position when the treatment liquid is supplied from the treatment liquid supply nozzle. It is possible to prevent contamination of a substrate during the treatment process.

### CROSS-REFERENCE TO RELATED APPLICATIONS

This application is based upon and claims the benefit of priority from the prior Japanese Patent Application No. 2016-73352, filed Mar. 31, 2016, and No. 2017-40452, filed Mar. 3, 2017, the entire contents both of which are incorporated herein by reference.

### FIELD

Embodiments of the present invention described herein relate to a substrate treating device and a substrate treating method.

### BACKGROUND

A substrate treating device performs, for example, a film forming process and a photo process to form a circuit pattern on a substrate, such as a wafer and a liquid crystal panel, etc. during a process of manufacturing semiconductors and the like. In these processes, mainly a single-wafer substrate treating device is used for a wet process using treatment liquids to perform a chemical liquid treatment, washing treatment, and drying treatment, etc. on a substrate (see, for example, Jpn. Pat. Appln. KOKAI Publication No. 2000-133625). In a single-wafer substrate treating device, the outer peripheral surface of a substrate is held, the substrate is rotated about an axis orthogonal to the surface of the substrate as a rotational axis, and a treatment liquid (for example, an etching liquid, a washing liquid, and pure water) is supplied to the surface of the rotating substrate.

In the substrate treating device, after a treatment liquid is supplied to the surface of a substrate, drying treatment is performed while the substrate is being rotated and a gas is being supplied to the surface of the substrate. In this drying treatment, a shield plate that is arranged facing the substrate and is in a size to cover the entire surface of the substrate is brought into proximity to the surface of the substrate, and a space formed between the substrate and the shield plate is supplied with a gas.

In such a device, a shield plate is usually arranged at a position in proximity to the substrate at the time of performing a treatment while a treatment liquid is being supplied to the surface of the substrate.

In some cases, the treatment liquid supplied to the surface of the substrate may splash on the surface of the substrate. If this phenomenon occurs, the splashed treatment liquid is made to adhere to the surface of the shield plate that faces the substrate in proximity to the substrate. If the shield plate with the treatment liquid still adhering thereto is used for drying treatment, the treatment liquid adhering to the shield plate would drop on the surface of the substrate, and this may cause water marks. This problem is not recognized in the above-noted patent document.

An object of the present invention is to satisfactorily perform a treatment for a substrate using treatment liquids.

### SUMMARY

A substrate treating device according to the embodiment, that rotates and washes a substrate, the device includes a spinning holding mechanism for holding a substrate, a treatment liquid supply nozzle for supplying a treatment liquid to the substrate, a shielding plate that is arranged opposite to the substrate held by the spinning holding mechanism and that moves in a contact/separate direction with respect to the substrate, a shielding plate rotating mechanism for rotating the shielding plate, and a control device for controlling the shielding plate rotating mechanism to locate the shielding plate at a standby position when the treatment liquid is not supplied and to rotate the shielding plate without moving the shielding plate from the standby position when the treatment liquid is supplied from the treatment liquid supply nozzle.

A substrate treating device according to the embodiment, that rotates and washes a substrate, includes a spinning holding mechanism for holding a substrate, a treatment liquid supply nozzle for supplying a treatment liquid to the substrate, a shielding plate that is arranged opposite to the substrate held by the spinning holding mechanism and that moves in a contact/separate direction with respect to the substrate, a shielding plate rotating mechanism for rotating the shielding plate, and a rear surface nozzle head for respectively supplying the treatment liquid and a gas to a rear surface of the substrate; and a control device, wherein the control device controls, for every first number of sheets that is preset, the shielding plate rotating mechanism to locate the shielding plate at a standby position when the treatment liquid is not supplied and to rotate the shielding plate without moving the shielding plate from the standby position when the treatment liquid is supplied from the treatment liquid supply nozzle, controls, for every second number of sheets that is preset, the rear surface nozzle head to respectively supply the treatment liquid and the gas to the shielding plate after the substrate is carried out from a treatment chamber, and controls, for every third number of sheets that is preset, the treatment liquid supply nozzle to supply the treatment liquid to a periphery of the shielding plate after the substrate is carried out from the treatment chamber.

A substrate treating method according to the embodiment, for rotating and washing a substrate, the method includes a substrate holding step of holding the substrate, a treatment liquid supply step of supplying a treatment liquid to the substrate from a treatment liquid supply nozzle, a shielding plate moving step of moving a shielding plate in a contact/separate direction with respect to the substrate, the shielding plate being arranged facing the substrate held in the substrate holding step, and a shielding plate rotating step of locating the shielding plate at a standby position when the treatment liquid is not supplied and rotating the shielding plate without moving the shielding plate from the standby position during the supply of the treatment liquid by the treatment liquid supply nozzle.

According to the embodiments of the present invention, it is possible to satisfactorily perform a treatment for a substrate using treatment liquids.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE DRAWINGS

The accompanying drawings, which are incorporated in and constitute apart of the specification, illustrate embodiments of the invention, and together with the general description given above and the detailed description of the embodiments given below, serve to explain the principles of the invention.

FIG. 1 is a plan view showing a schematic structure of a substrate treating device according to a first embodiment.

FIG. 2 is a diagram of showing a schematic structure of a treatment chamber according to the first embodiment.

FIG. 3 is a cross-sectional view of a structure of a shielding plate according to the first embodiment.

FIG. 4 is a diagram showing a series of treatment operations according to the first embodiment.

FIG. 5 is a diagram showing treatment operations according to a second embodiment.

FIG. 6 is a diagram showing treatment operations according to a third embodiment.

### DETAILED DESCRIPTION

### First Embodiment

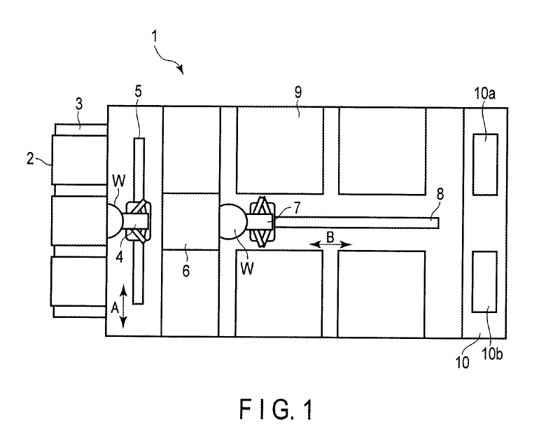

The first embodiment will be explained with reference to FIG. 1 to FIG. 4.

As shown in FIG. 1, a substrate treating device 1 according to the first embodiment comprises a substrate storing case 2, a mount table 3, a transfer robot 4, a transfer guide rail 5, a buffer table 6, a transfer robot 7, a transfer guide rail 8, a treatment chamber 9, and an accessory unit 10.

The substrate storing case 2 is a container for storing a substrate W (for example, a substrate wafer). Substrates W are separately laminated and stored in the substrate storing case 2 with a predetermined space therebetween.

The mount table 3 is a table for placing the substrate storing case 2. A plurality of the substrate storing cases 2 can be placed in a line with a certain interval therebetween as shown in FIG. 1.

The transfer robot 4 is provided next to the line of the substrate storing cases 2 so that the transfer robot 4 moves along a first transfer direction (the direction of arrow A indicated in FIG. 1) in which the plurality of the substrate storing cases 2 are lined. This transfer robot 4 retrieves an untreated substrate W stored in a substrate storing case 2. Then, the transfer robot 4 moves in the direction of arrow A as needed and stops near the buffer table 6, and turns around at the location where it stops to transfer the substrate W to the buffer table 6. The transfer robot 4 retrieves a treated substrate W from the buffer table 6, and moves in the direction of arrow A as needed to transfer the treated substrate W to a desired substrate storing case 2. The transfer robot 4 may be configured only to turn to transfer an untreated substrate W to the buffer table 6, or a treated substrate W to a desired substrate storing case 2. As the transfer robot 4, a publicly-known robot having, for example, a robot arm, a robot hand, and a moving mechanism, can be used.

The transfer guide rail 5 is a mechanism for moving the transfer robot 4 in the direction of arrow A. Thus, it is possible to make the transfer robot 4 move to transfer a substrate W between each of the substrate storing cases 2 and the buffer table 6. This transfer guide rail 5 is, for example, a linear motion (LM) guide.

The buffer table 6 is provided near the center of the transfer guide rail 5 on which the transfer robot 4 moves, and on the opposite side of the mount table 3. This buffer table 6 is a mount table to hand over a substrate W between the transfer robot 4 and the transfer robot 7.

The transfer robot 7 is provided in such a manner that the robot moves from the buffer table 6 in a second transfer direction (the direction of arrow B indicated in FIG. 1) orthogonal to the direction in which the transfer robot 4 transfers (the direction of arrow A). This transfer robot 7 retrieves a substrate W placed on the buffer table 6, moves in the direction of arrow B as needed, stops near a desired treatment chamber 9, and turns around at the location where it stops to transfer the substrate W to the desired treatment chamber 9. The transfer robot 7 also retrieves a processed substrate W from a treatment chamber 9, moves in the direction of arrow B as needed and stops near the buffer table 6, and turns around on the location where it stops to transfer the treated substrate W to the desired buffer table 6. As the transfer robot 7, a publicly-known robot having, for example, a robot arm, a robot hand, and a moving mechanism, can be used.

The transfer guide rail 8 is a mechanism for making the transfer robot 7 move in the direction of arrow B. With this mechanism, it is possible to make the transfer robot 7 move to transfer a substrate W between each of the treatment chambers 9 and the buffer table 6. This transfer guide rail 8 is, for example, a linear motion (LM) guide.

Two treatment chambers 9, for example, are provided on each of the sides of the transfer guide rail 8 on which the transfer robot 7 moves. In the present embodiment, the treatment chamber 9 supplies a treatment liquid to and performs washing treatment on a substrate W transferred by the transfer robot 7. Drying treatment is also performed to dry a substrate W for which washing treatment is completed. The details will be described later.

The accessory unit 10 is provided on one end of the transfer guide rail 8 and on the opposite side of the buffer table 6, in other words, on one end of the substrate processing device 1. This accessory unit 10 stores a gas/liquid supply unit 10a and a control unit (control device) 10b. The gas/liquid supply unit 10a supplies each treatment chamber 9 with various treatment liquids (for example, pure water, a mixed solution of ammonia water and oxygenated water (APM), isopropyl alcohol (IPA), etc.), and gases (for example, nitride gas, etc.). The control unit 10b includes a microcomputer that intensively controls each section, a storage section for storing substrate treatment information, and various programs related to substrate treatment (both not illustrated). The control unit 10b controls each section, such as the transfer robot 4, the transfer robot 7, and each of the treatment chambers 9, etc. based on the substrate treatment information and various programs.

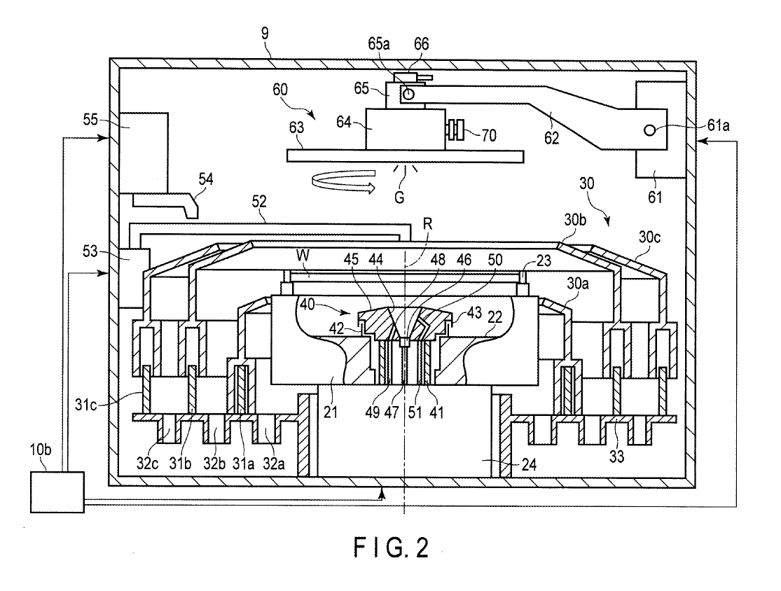

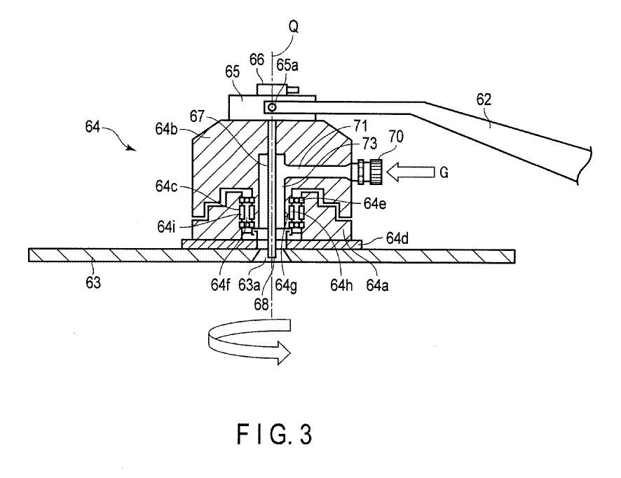

Next, the internal configuration of the treatment chamber 9 will be explained with reference to FIG. 2 and FIG. 3.

As shown in FIG. 2, the treatment chamber 9 has a spinning holding mechanism 21, a cup body 30, a rear surface nozzle head 40, a first nozzle 52, a first nozzle moving mechanism 53, a second nozzle 54, a second nozzle moving mechanism 55, and a shielding mechanism 60. The spinning holding mechanism 21, the cup body 30, the rear surface nozzle head 40, the first nozzle 52, the first nozzle moving mechanism 53, the second nozzle 54, the second nozzle moving mechanism 55, and the shielding mechanism 60 are provided inside the treatment chamber 9.

The treatment chamber 9 is formed in a rectangular-parallelepiped shape, and has a shutter (not illustrated). The shutter is openably and closably formed on a wall surface on the side of the transfer guide rail 8 in the treatment chamber 9. The shutter is open or closed when a substrate W is carried into or out of the treatment chamber 9. The inside of the treatment chamber 9 is kept clean by down flows (vertical laminar flows).

The spinning holding mechanism 21 is a mechanism for holding a substrate W in a horizontal state and for rotating a substrate W in a horizontal plane around a central axis R which is perpendicular to a treated surface of a substrate W. The spinning holding mechanism 21 has a rotation body 22 which constitutes a base. Six support pins 23 are formed with a predetermined interval therebetween, for example, with an interval of 60 degrees, on the circumferential direction of the rotation body 22. The support pins 23 are abutted to the edge surface of a substrate W to hold the substrate W in a horizontal state in the cup body 30. The spinning holding mechanism 21 has a rotation mechanism 24 having a rotation axis and a motor, etc. underneath the rotation body 22. The rotation mechanism 24 enables the spinning holding mechanism 21 to rotate a substrate W while holding the substrate W in a horizontal state. The spinning holding mechanism 21 is electrically connected to the control unit 10b. The holding and rotating of a substrate W by the spinning holding mechanism 21 is controlled by the control unit 10b.

The cup body 30 includes three upper cups 30a, 30b, and 30c, three lower cups 31a, 31b, and 31c, and a bottom portion 33. The upper cups 30a to 30c and the lower cups 31a to 31c are formed in a cylindrical shape so as to circumferentially surround the substrate W held by the spinning holding mechanism 21. The upper portion of the cup body 30, i.e., the upper cups 30a to 30c, are open so that the front surface (upper surface) of a substrate W held by the spinning holding mechanism 21 is entirely exposed, and the peripheral wall of each of the upper portions is inclined inwardly in the radial direction.

The upper cup 30a and the lower cup 31a are disposed around the outer periphery of the spinning holding mechanism 21. The upper cup 30b and the lower cup 31b are disposed around the outer periphery of the upper cup 30a and the lower cup 31a. The upper cup 30c and the lower cup 31c are disposed around the outer periphery of the upper cup 30b and the lower cup 31b.

The lower cups 31a to 31c are formed being vertically fixed with respect to the bottom portion 33, and slidably inserted between the corresponding peripheral walls of a dual structure formed underneath each of the upper cups 30a to 30c, thereby constituting a labyrinth structure. The upper cups 30a to 30c are separately and vertically drivable by an upward/downward driving mechanism, which is not illustrated. In the bottom portion 33, a discharging port 32a is formed in a region surrounded by the lower cup 31a, a discharging port 32b is formed in a region surrounded by the lower cup 31a and the lower cup 31b, and a discharging port 32c is formed in a region surrounded by the lower cup 31b and the lower cup 31c. The discharging ports 32a to 32c are respectively connected to a discharging pipe, a drainage tank, and an exhaust pump via a gas-liquid separator (all unillustrated). Thus, it is possible to separate and collect a treatment liquid scattered from the substrate W through each of the discharging ports 32a to 32c. The upward/downward driving mechanism is electrically connected to the control unit 10b. The upward/downward driving of the upper cups 30a to 30c is controlled by the control unit 10b.

The rear surface nozzle head 40 is supported in a fixing state on the upper edge of the fixing axis 41. The fixing axis 41 penetrates the rotation mechanism 24 in a non-contact manner and is fixed to the bottom portion 33 in the treatment chamber 9. There is a space between the rear surface nozzle head 40 supported on the upper edge of the fixing axis 41 and the rotation body 22. Thus, the rear surface nozzle head 40 is configured to be in a fixed state and to not rotate with the rotation body 22. The rear surface nozzle head 40 is projected on the upper surface side of the rotation body 22, and on the upper surface of the rotation body 22, an annular wall 42 is formed upwardly at a position corresponding to the outer periphery of the rear surface nozzle head 40. On the other hand, on the outer periphery of the rear surface nozzle head 40, an annular recessed groove 43 for storing the annular wall 42 inside therein is formed, opening toward the bottom surface. In other words, the annular wall 42 and the annular recessed groove 43 form a labyrinth structure to prevent a treatment liquid splashed on the upper surface side of the rotation body 22 from flowing outside of the cup body 30 along the fixing axis 41.

In the rear surface nozzle head 40, a recessed portion 44 with an open upper surface is formed as shown in FIG. 2. The recessed portion 44 is formed in a conical shape which is radially decreased from the top to the bottom. In the peripheral portion of the recessed portion 44 on the upper surface of the rear surface nozzle head 40, an inclined surface 45 that is inclined outwardly in the radial direction is formed.

One end of the drainage port 46 that constitutes a drainage portion opens at the bottom portion of the recessed portion 44. The drainage port 46 is to drain a treatment liquid that is ejected onto the rear surface of a substrate W, but is deflected back by the substrate W and dropped into the inner surface of the recessed portion 44. The other end of the drainage port 46 is connected to one end of the drainage pipe 47. The other end of the drainage pipe 47 is, although not illustrated, connected to an exhaust pump via a gas-liquid separator, like the discharging ports 32a to 32c.

A lower treatment liquid nozzle 48 and a lower treatment gas nozzle 50 are formed on the surface of the recessed portion 44. The lower treatment liquid nozzle 48 is connected to one end of a treatment liquid supply pipe 49, and the lower treatment gas nozzle 50 is connected to one end of a gas supply pipe 51. The other ends of the treatment liquid supply pipe 49 and the gas supply pipe 51 are respectively connected to the gas/liquid supply unit 10a. A plurality of lower treatment liquid nozzles 48 and lower treatment gas nozzles 50 may be disposed on the surface of the recessed portion 44 with a certain interval therebetween. In the present embodiment, two lower treatment liquid nozzles 48 and two lower treatment gas nozzles 50 are disposed at an interval approximately of 90 degrees on the circumferential direction of the recessed portion 44.

A treatment liquid S (for example, APM) and a treatment liquid L (for example, pure water) supplied through the treatment liquid supply pipe 49 are ejected from the lower treatment liquid nozzle 48 toward the rear surface of a substrate W held by the spinning holding mechanism 21. A gas G (for example, nitride) supplied through the gas supply pipe 51 is ejected from the lower treatment gas nozzle 50 toward the rear surface of a substrate.

The direction of ejection from each of the lower treatment liquid nozzle 48 and the lower treatment gas nozzle 50 is inclined for a predetermined angle with respect to the central axis R, so that the treatment liquids S and L and the gas G can be ejected toward the approximate rotational center of a substrate W held by the spinning holding mechanism 21.

The treatment liquids S and L supplied to a rotating substrate W spread on the rear surface of the substrate W almost entirely by centrifugal force, and most of the treatment liquid deflected back by the substrate W drops into the recessed portion 44. The gas G also acts almost entirely on the rear surface of the substrate W, similar to the treatment liquids S and L.

The treatment liquids S and L may be ejected toward a position off of the rotational center of a substrate W. Similarly, the gas G may also be ejected toward a position off of the rotational center of a substrate W. The supply of the treatment liquids S and L and the gas G is controlled by the control unit 10b.

A first nozzle 52 supplies the surface of a substrate W supported by the spinning holding mechanism 21 with the treatment liquid L (for example, pure water). The first nozzle 52 is configured to be swingable by a first nozzle moving mechanism 53 along the front surface of a substrate W supported by the spinning holding mechanism 21. The first nozzle 52 is supplied with the treatment liquid L from the gas/liquid supply unit 10a via piping (not illustrated).

The first nozzle moving mechanism 53 is composed of a rotating shaft, a motor, and the like. For example, the first nozzle moving mechanism 53 makes the first nozzle 52 move to a liquid supply position and a displacement position. The liquid supply position is a position facing the proximity of the center of the surface of a substrate W held by the spinning holding mechanism 21, and the displacement position is a position where the nozzle is displaced from the liquid supply position to allow a substrate W to be carried into and out and performing drying treatment on a substrate W.

A second nozzle 54 is a spray nozzle. The second nozzle 54 supplies the surface of a substrate W held by the spinning maintaining mechanism 21 with a mist of the treatment liquid S. The second nozzle 54 is configured to be swingable by a second nozzle moving mechanism 55 on the surface of a substrate W held by the spinning holding mechanism 21. The second nozzle 54 is supplied with a treatment liquid S from the gas/liquid supply unit 10a via piping (not illustrated).

The second nozzle moving mechanism 55 is composed of a rotating shaft and a motor, etc., like the first nozzle moving mechanism 53. For example, the second nozzle moving mechanism 55 makes the second nozzle 54 move to a liquid supply position and a displacement position. The first nozzle moving mechanism 53 and the second nozzle moving mechanism 55 are electrically connected to the control unit 10b. The movement of each of the nozzles and the operation of supplying treatment liquids are controlled by the control unit 10b.

The shielding mechanism 60 is configured to include a shielding plate raising and lowering mechanism 61, an arm 62, a shielding plate 63, a shielding plate rotating mechanism 64, and a shielding plate holding mechanism 65, as shown in FIGS. 2 and 3.

The shielding plate raising and lowering mechanism 61 has a rotational member 61a having an axis orthogonal to the central axis R (the direction orthogonal to this paper). One end of the arm 62 is fixed to the rotational member 61a. When the shielding plate raising and lowering mechanism 61 rotationally moves the rotational member 61a in a range of a certain angle, the arm 62 makes an arc motion around the rotational member 61a as an axis. The shielding plate raising and lowering mechanism 61 makes the arm 62 move in an arc motion to move the shielding plate 63 in a contact/separate direction (upward/downward direction), as will be described later.

The other end of the arm 62 is connected to the shielding plate holding mechanism 65 via a connecting pin 65a. The connecting pin 65a is disposed in a direction orthogonal to the central axis R, similar to the above-described rotational member 61a. Rotational axis bearings (not illustrated) are interposed in each of the connecting portions where the connecting pin 65a and the arm 62 are connected and the connecting portions where the connecting pin 65a and the shielding plate holding mechanism 65 are connected, so that the shielding plate 63 can be moved upwardly and downwardly maintaining a horizontal state when the arm 62 is swung by the actuation of the shielding plate raising and lowering mechanism 61.

As shown in FIG. 3, the shielding plate 63 is a disk-shaped member having a circular nozzle opening 63a and a central axis Q in the center thereof. The diameter of the shielding plate 63 is approximately the same as that of a substrate W, for example. The diameter of the shielding plate 63 may be slightly greater than that of a substrate W; however, it is set slightly smaller than the size of a substrate W in the present embodiment. This is to prevent the shielding plate 63 from interfering with the support pins 23 when a distance between the shielding plate 63 and the substrate W is shortened. The shielding plate 63 is fixed to a connecting plate 64d by a screw (not illustrated) underneath the lower portion of the shielding plate rotating mechanism 64.

The shielding plate rotating mechanism 64 is configured to include a rotation body 64a, a main body 64b, a motor 64c, and a connecting plate 64d. In the inside of the rotation body 64a and the main body 64b, a gas supply nozzle 73 in the shape of a circle in a cross section is formed with respect to the central axis Q. One end of the gas supply nozzle 73 is inserted through the nozzle opening 63a. On the side wall side of the main body 64b, a gas supply opening 70 is provided and connected to one end of a gas introduction path 71. The other end of the gas introduction path 71 is connected to the gas supply nozzle 73, and when the gas G is supplied from the gas supply opening 70, the gas G is supplied to the substrate W from the nozzle opening 63a. In the inside of the gas supply nozzle 73, a treatment liquid supply nozzle 67 for ejecting a treatment liquid P (for example, an isopropyl alcohol (IPA)) onto the front surface of a substrate W is formed along the central axis Q. One end of the treatment liquid supply nozzle 67 penetrates the shielding plate holding mechanism 65 and is connected to the treatment liquid introducing portion 66. The other end of the treatment liquid supply nozzle 67 constitutes a nozzle discharging port 68. The nozzle discharging port 68 is located at the center of the nozzle opening 63a. The treatment liquid supply nozzle 67 is circularly formed in a cross section around the central axis Q, similar to the gas supply nozzle 73 and the nozzle opening 63a. The upper portion of the rotation body 64a is in a concave shape, and an opening 64f is provided at the center thereof. The bottom portion of the main body 64b is formed in a convex shape so as to correspond to the concave shape, and a space is formed between the surfaces of the convex portion and the concave portion facing each other. The center of the main body 64b is provided with a projecting portion 64g that is formed so as to surround the gas supply nozzle 73. The projecting portion 64g is inserted into the opening 64f. A space is formed between the inner surface of the opening 64f and the outer surface of the projecting portion 64g. Bearings 64e are provided in the space, and the rotation body 64a is supported by the main body 64b in a non-contact manner. The bearings 64e are, for example, bearings for a rotation axis.

The motor 64c is provided in a space between the inner surface of the opening 64f and the outer surface of the projecting portion 64g. For example, on the outer surface of the projecting portion 64g, a plurality of coils 64h corresponding to a stator of the motor 64c are provided in a fixed manner, and on the inner surface of the opening 64f, a permanent magnet 64i corresponding to a rotator of the motor 64c is provided in a fixed manner. The permanent magnet 64i forms a ring shape in such a manner that the polarity is inverted for every predetermined angle, and is arranged opposite to the coil 64h. Accordingly, when a current flows in the coil 64h, the rotation body 64a and the shielding plate 63 rotate about the central axis Q integrally with the permanent magnet 64i.

The shielding plate holding mechanism 65 is a member connecting the arm 62 with the main body 64b, and it is provided above the main body 64b in a fixed manner. A hole (not illustrated) into which a connecting pin 65a can be inserted is provided in the center of the shielding plate holding mechanism 65.

A treatment liquid introducing portion 66 is provided above the shielding plate holding mechanism 65. One end of the treatment liquid introducing portion 66 is connected to the treatment liquid supply nozzle 67 that penetrates the shielding plate holding mechanism 65. The other end of the treatment liquid introducing portion 66 is connected to a supply pipe (not illustrated) for supplying the treatment liquid P from the gas/liquid supply unit 10a. The shielding plate raising and lowering mechanism 61 and the shielding plate rotating mechanism 64 are electrically connected to the control unit 10b. The raising/lowering and rotating of the shielding plate 63 is controlled by the control unit 10b.

Next, a substrate treatment operation is explained. First, a substrate W is retrieved from the substrate storing case 2 by the transfer robot 4. The transfer robot 4 moves along the transfer guide rail 5 as needed, and turns around on the location where it stops to carry the substrate W into the buffer table 6. Or, the transfer robot 4 does not move along the transfer guide rail 5, but turns around to carry the substrate W into the buffer table 6. After that, the substrate W carried into the buffer table 6 is retrieved by the transfer robot 7. The transfer robot 7 moves along the transfer guide rail 8 close to a desired treatment chamber 9 as needed, and turns around on the location where it stops to carry the substrate W into the desired treatment chamber 9. Or, the transfer robot 7 does not move along the transfer guide rail 8, but turns around to transfer the substrate W to the desired treatment chamber 9. At this time, the shutter of the treatment chamber 9 is open.

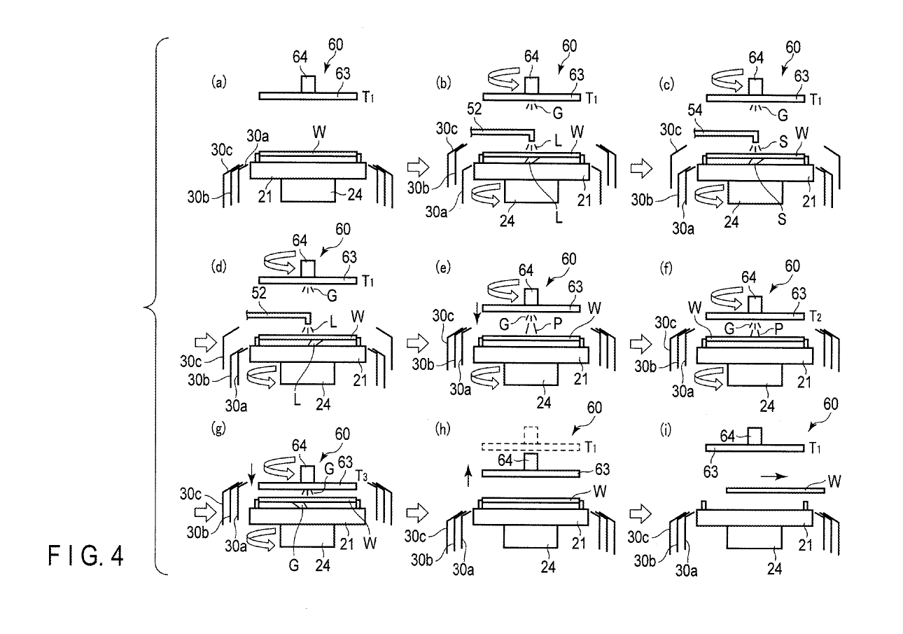

The substrate W carried into the treatment chamber 9 is held by the spinning holding mechanism 21. At this time, the upper cups 30a to 30c are lowered, as shown in FIG. 4 (a). The shielding plate 63 of the shielding mechanism 60 is located at a standby position (the position indicated by T1 in FIG. 4). The standby position is a position located above the spinning holding mechanism 21 as shown in FIG. 4 (a), and where the transfer of the substrate W is not impeded when the substrate W is carried into the treatment chamber 9 by the transfer robot 7.

Then, the transfer robot 7 is displaced from the treatment chamber 9 and the shutter is closed.

Next, as shown in FIG. 4 (b), the upper cup 30b and the upper cup 30c are raised by the upward/downward driving mechanism. The substrate W held by the spinning holding mechanism 21 is rotated at a low speed (for example, 500 rpm) by the rotation mechanism 24. At the same time as the rotation of the substrate W, the first nozzle 52 is moved to the center of the substrate W by the first nozzle moving mechanism 53.

A gas G is supplied from the gas supply opening 70, and the gas G is ejected from the gas supply nozzle 73. The ejection of the gas G is, as will be described later, executed to prevent the treatment liquid L and the treatment liquid S supplied to the front surface of the substrate W from entering a nozzle opening 63a and a nozzle discharging port 68 when the liquids splash on the front surface of the substrate W. The ejection amount of gas is, for example, about 50 liters per minute. As will be described later, the supply of the gas G from the gas supply nozzle 73 in this state continues immediately before the state illustrated in FIG. 4 (g), in other words, immediately before the shielding plate 63 is located at a drying treatment position T3.

Next, a treatment liquid L is supplied to the center of the front surface of the substrate W from the first nozzle 52. Thus, particles adhering to the surface of the substrate W can be removed. The treatment liquid L spreads toward the outer periphery of the substrate W by centrifugal force of the rotating substrate W, and scatters from the outer periphery of the substrate W. The treatment liquid L scattered from the substrate W collides with the inner surface of the raised upper cup 30b, and flows down to the discharging port 32b along the inner peripheral surface. The flowed-down treatment liquid L is collected through the discharging pipe connected to the discharging port 32b.

When the treatment liquid L is supplied to the surface of the substrate W, the shielding plate 63 of the shielding mechanism 60 is rotated by the shielding plate rotating mechanism 64 while being located at the standby position T1. The rotational frequency of the shielding plate 63 is fixed (for example, 500 rpm). The rotation direction is the same as the rotation direction of the substrate W. The droplets of the treatment liquid L adhering to the surface of the shielding plate 63 that faces the substrate W as a result of the splash of the treatment liquid L on the front surface of the substrate W is shaken off and removed by centrifugal force by the rotation of the shielding plate 63. By removing the droplets of the treatment liquid L adhering to the surface of the shielding plate 63 that faces the substrate W, it is possible to prevent the droplets of the treatment liquid L from falling onto the front surface of the substrate W from the shielding plate 63. If the droplets of the treatment liquid L adhering to the surface of the shielding plate 63 that faces the substrate W remain, they may solidify and cause particles; however, this can also be prevented.

At the same time as the supply of the treatment liquid L to the front surface of the substrate W from the first nozzle 52, the treatment liquid L is supplied to the rear surface of the substrate W from the lower treatment liquid nozzle 48. Thus, particles adhering to the rear surface of the substrate W can be removed. The treatment liquid L supplied to the rear surface of the substrate W spreads toward the outer periphery of the substrate W, and scatters from the outer periphery of the rear surface of the substrate W. The treatment liquid L scattered from the outer periphery of the rear surface of the substrate W collides with the inner surface of the raised upper cup 30b, and flows down toward the discharging port 32b along the inner surface. The dropped treatment liquid L is collected through the discharging pipe connected to the discharging port 32b. The time of supplying the treatment liquid L is preset; for example, 10 seconds in the present embodiment.

When the preset time is elapsed, the supply of the treatment liquid L from the first nozzle 52 and the lower treatment liquid nozzle 48 is stopped. The first nozzle 52 is moved to a displacement position by the first nozzle moving mechanism 53.

Next, as shown in FIG. 4 (c), the upper cup 30b is lowered by the upward/downward driving mechanism, while the upper cup 30c remains raised. The second nozzle 54 is moved to the center of the substrate W by the second nozzle moving mechanism 55. Then, at the same time as the supply of a mist of the treatment liquid S to the front surface of the substrate W from the second nozzle 54, the second nozzle 54 swings by the second nozzle moving mechanism 55, as going back and forth between the center of the substrate W and the periphery of the substrate W. At the same time as the supply of a mist of the treatment liquid S to the front surface of the substrate W, the treatment liquid S is supplied to the rear surface of the substrate W from the lower treatment liquid nozzle 48. The treatment liquid S in a liquid form is supplied from the lower treatment liquid nozzle 48. The treatment liquid S removes particles including oxides adhering to the substrate W. The supply of the treatment liquid S herein is made in a preset time; for example, 30 seconds in the present embodiment.

While the treatment liquid S is being supplied to the front surface of the substrate W, the shielding plate 63 is rotated at the standby position T1. Thus, it is possible to shake off and remove the droplets of the treatment liquid S adhering to the surface of the shielding plate 63 that faces the substrate W as a result of the splashes of the treatment liquid S supplied to the front surface of the substrate W by centrifugal force. Thus, it is possible to prevent the droplets of the treatment liquid S from dropping onto the front surface of the substrate W from the surface of the shielding plate 63 that faces the substrate W. If the droplets of the treatment liquid S adhering to the surface of the shielding plate 63 that faces the substrate W remain, they may solidify and cause particles; however, this can also be prevented.

A mist of the treatment liquid S supplied to the substrate W is caused to scatter from the outer periphery of the substrate W by the rotation of the substrate W. The scattered mist of the treatment liquid S collides with the inner surface of the raised upper cup 30c, and drops into the discharging port 32c along the inner peripheral surface. The dropped mist of the treatment liquid S is collected through the discharging port 32c. The treatment liquid S supplied to the rear surface of the substrate W also scatters from the outer periphery of the rear surface of the substrate W, and is collected by the raised upper cup 30c.

When the preset time is elapsed, the supply of a mist of the treatment liquid S from the second nozzle 54 and the supply of the treatment liquid S from the lower treatment liquid nozzle 48 are stopped. Then, the second nozzle 54 is moved to the displacement position by the second nozzle moving mechanism 55.

As shown in FIG. 4 (d), the upper cup 30b remains lowered, similar to the operation illustrated in FIG. 4 (c), and the upper cup 30c remains raised. The first nozzle 52 is moved from the displacement position to the center of the substrate W by the first nozzle moving mechanism 53. Furthermore, the substrate W is rotated at a high speed (for example, 1000 rpm). At the same time as the supply of the treatment liquid L to the center of the front surface of the substrate W from the first nozzle 52, the treatment liquid L is supplied to the rear surface of the substrate W from the lower treatment liquid nozzle 48. Thus, a mist of the treatment liquid S adhering to the front surface of the substrate W treated in a preceding step and the treatment liquid S adhering to the rear surface of the substrate W can be washed away by the treatment liquid L. Since the substrate W is rotated at a high speed, the discharge of the treatment liquid S can be improved.

The treatment liquid L scatters from the outer periphery of the front surface of the substrate W and the outer periphery of the rear surface of the substrate W, collides with the inner surface of the upper cup 30c, and drops into the discharging port 32c along the inner surface. Then, the dropped treatment liquids are collected through the discharging pipe.

As the rotation of the shielding plate 63 continues at the standby position T1, it is possible to remove the treatment liquid L adhering to the surface of the shielding plate 63 that faces the substrate W as a result of the splash of the treatment liquid L supplied to the front surface of the substrate W. Thus, it is possible to prevent the droplets of the treatment liquid L from falling onto the front surface of the substrate W from the shielding plate 63. If the droplets of the treatment liquid L adhering to the surface of the shielding plate 63 that faces the substrate W remain, they may solidify and cause particles; however, this can also be prevented.

The time of supplying the treatment liquid L is preset, and it is 10 seconds in the present embodiment.

Next, when the preset time is elapsed, the supply of the treatment liquid L from the first nozzle 52 and the lower treatment liquid nozzle 48 is stopped. Then, the first nozzle 52 is moved to the displacement position by the first nozzle moving mechanism 53.

As shown in FIG. 4 (e), the upper cups 30a and 30b are raised by the upward/downward driving mechanism, and the substrate W is rotated at a low speed (for example, 10 rpm). Then, the shielding plate 63 is lowered to the treatment liquid supply position (the position indicated by T2 in FIG. 4 (f)) by the shielding plate raising and lowering mechanism 61, and is brought near the substrate W. Along with the lowering, the treatment liquid P is supplied to the front surface of the substrate W from the treatment liquid supply nozzle 67. The supply of the treatment liquid P may begin concurrently with the lowering of the shielding plate 63, or may start during the lowering, as shown in FIG. 4 (f).

Next, the lowering of the shielding mechanism 60 is finished (FIG. 4 (f)). Even after the shielding mechanism 60 is located at the treatment liquid supply position T2, the supply of the treatment liquid P continues within a preset time (for example, 3 seconds). The treatment liquid supply position T2 is a position where the distance between the front surface of the substrate W and the shielding plate 63 does not allow the splashes of the treatment liquid P supplied to the front surface of the substrate W from the treatment liquid supply nozzle 67 to go over the cup body 30 and be scattered. The supply of the gas G from the gas supply nozzle 73 continues while the treatment liquid P is being supplied.

The treatment liquid P supplied to the substrate W washes away the treatment liquid L supplied to the front surface of the substrate W in a preceding step. The treatment liquid L is thus replaced with the treatment liquid P in the front surface of the substrate W. At this time, the supplied treatment liquid P is scattered from the outer periphery of the surface of the substrate W by centrifugal force of the rotating substrate W with the washed-away treatment liquid L, and they collide with the inner surface of the upper cup 30a, and drop toward the discharging port 32a along the inner surface of the upper cup 30a. Then, the dropped treatment liquids are collected through the discharging pipe.

When the supply of the treatment liquid P is stopped at the treatment liquid supply position T2, the shielding plate 63 is lowered to the drying treatment position (the position indicated by T3 in FIG. 4) as shown in FIG. 4 (g), and is brought closer the substrate W. When the shielding plate 63 is located at the drying treatment position T3, the flowing amount of the gas G exhausted from the gas supply nozzle 73 (for example, 250 liters per minute), and the space between the shielding plate 63 and the substrate W is filled with the gas G. Thus, since the air near the front surface of the substrate W can be reduced, oxygen that causes the occurrence of water marks near the front surface of the substrate W can be blocked out. The substrate W is rotated at a high speed (for example, 1000 rpm) at this time. Thus, the treatment liquid P present on the front surface of the substrate W is shaken off by centrifugal force applied to the substrate W due to the high-speed rotation. The drying treatment of the substrate W is performed in such a manner. The treatment liquid P scattered onto the inner surface of the upper cup 30a from the periphery of the substrate W drops toward the discharging port 32a along the inner surface of the upper cup 30a. Then, the liquid is collected through the discharging pipe. At the same time as the supply of the gas G to the front surface of the substrate W, the gas G is supplied to the rear surface of the substrate W from the lower treatment gas nozzle 50. The drying treatment is performed within a preset time, for example, 10 seconds.

Next, when the preset time of drying treatment is elapsed, the rotation of the substrate W and the rotation of the shielding plate 63 are stopped, and so is the supply of the gas G. Then, as shown in FIG. 4 (h), the upper cups 30a to 30c are lowered by the upward/downward driving mechanism, and the shielding plate 63 is raised to the standby position T1 by the shielding plate raising and lowering mechanism 61.

Next, as shown in FIG. 4 (i), the holding of the substrate W by the support pins 23 is released, and the substrate W is carried out from the treatment chamber 9 by the transfer robot 7.

As explained in the foregoing, according to the first embodiment, the shielding plate 63 of the shielding mechanism 60 is rotated at the standby position T1 while a treatment liquid L and a treatment liquid S are being supplied to the front surface of a substrate W. Consequently, even when the treatment liquids L and S supplied to the front surface of the substrate W become droplets and are adhering to the surface of the shielding plate 63 that faces the substrate W as a result of splashing on the front surface of the substrate W, it is possible to shake off and remove the liquids by centrifugal force caused by the rotation of the shielding plate 63 before the shielding plate 63 is lowered to the treatment liquid supply position T2. Thus, it is possible to prevent the droplets of the treatment liquid L or the treatment liquid S from falling onto and adhering to the front surface of the substrate W from the surface of the shielding plate 63 that faces the substrate W when the shielding plate 63 is brought near the substrate W for drying treatment, thereby preventing degradation of the substrate W. Particularly, it is possible to prevent occurrence of water marks on a treated surface of a substrate W. Thus, treatment for a substrate using treatment liquids can be satisfactorily performed.

Furthermore, the treatment liquid P (such as IPA) is supplied from the treatment liquid supply nozzle 67 when no treatment liquids L and S adhere to the surface of the shielding plate 63 that faces the substrate W. Accordingly, it is possible to efficiently replace the treatment liquid L on the substrate W with the treatment liquid P, such as IPA.

When the shielding plate 63 is brought near the substrate W for drying treatment, the rotation of the shielding plate 63 may be stopped.

### Second Embodiment

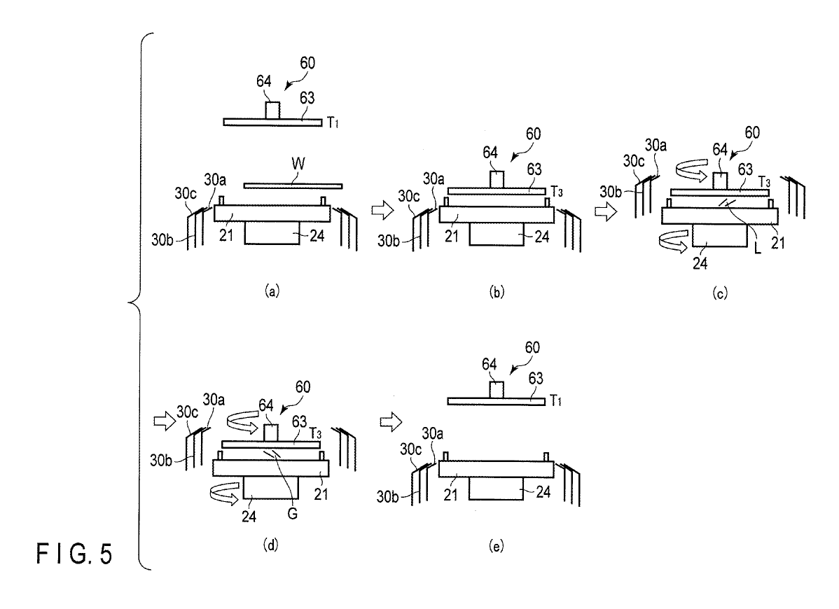

The second embodiment will be described with reference to FIG. 5.

FIGS. 5 (a) to (e) illustrate a shielding plate washing process for washing the shielding plate 63. The process is performed when the treatment of a substrate W is completed, after the substrate W is carried out of the treatment chamber 9 and before an untreated substrate W is carried into the treatment chamber 9. As a device that performs this shielding plate washing process, a same device as the device in the first embodiment can be used.

What is illustrated in FIG. 5 (a) is that the treatment of the substrate W is completed, the upper cups 30a to 30c are lowered, the shielding plate 63 is raised to the standby position T1, and the substrate W is carried out (the same state as illustrated in FIG. 4 (i)).

After carrying out the substrate W, the shielding plate 63 is lowered to the drying treatment position T3, as shown in FIG. 5 (b). Then, the shielding plate 63 and the spinning holding mechanism 21 are rotated as shown in FIG. 5 (c). Herein, the upper cups 30a to 30c are raised by the upward/downward driving mechanism. The treatment liquid L is supplied to the surface (lower surface) of the shielding plate 63 that faces the substrate W from the lower treatment liquid nozzle 48. The treatment liquid L supplied to the shielding plate 63 is caused to scatter from the outer periphery of the shielding plate 63 by centrifugal force of the rotation of the shielding plate 63, and is collected to the inner surface of the upper cup 30a.

When the supply of the treatment liquid L from the lower treatment liquid nozzle 48 is stopped, the gas G is supplied from the lower treatment gas nozzle 50 toward the lower surface of the shielding plate 63, as shown in FIG. 5 (d). Then, the treatment liquid L adhering to the lower surface of the shielding plate 63 is removed by the rotation of the shielding plate 63 and the supply of the gas G. Thus, the lower surface of the shielding plate 63 can be dried.

When the supply of the gas G from the lower treatment gas nozzle 50 is finished, the rotation of the shielding plate 63 and the rotation of the spinning holding mechanism 21 are stopped, as shown in FIG. 5 (e). Furthermore, the shielding plate 63 is raised to the standby position T1, and the upper cups 30a to 30c are lowered.

As explained above, after the substrate W is carried out of the treatment chamber 9, the lower surface of the shielding plate 63 is washed and dried. Thus, this configuration has the same advantageous effect as the first embodiment. Furthermore, the droplets of each treatment liquid adhering to the lower surface of the shielding plate 63 is removed by washing while the substrate W is being treated; thus, it is possible to improve the level of washing for the shielding plate 63, and treatment on a substrate using treatment liquids can be more satisfactorily performed.

In the present embodiment, the same lower treatment liquid nozzle 48 and lower treatment gas nozzle 50 are used for the washing treatment and the drying treatment for the lower surface of the shielding plate 63 as those used for the treatment of the rear surface of a substrate W. Thus, there is no need of providing a dedicated device for washing and drying the shielding plate 63, thereby preventing the substrate treating device 1 from being upsized.

The process of washing the shielding plate 63 may be performed after the treatment of a predetermined number of substrates, not after every time a substrate W is carried out.

### Third Embodiment

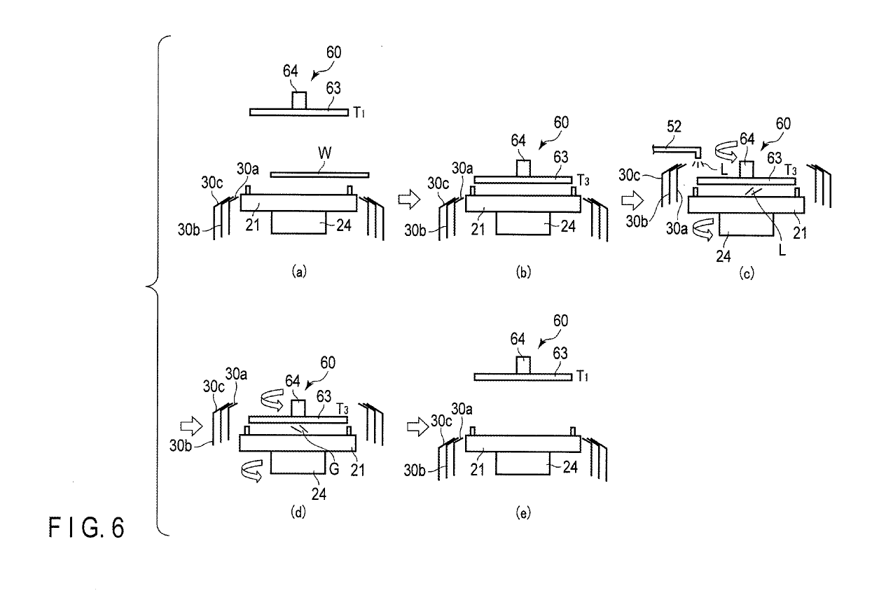

The third embodiment will be explained with reference to FIG. 6. Herein, the third embodiment will be explained with respect to differences from the second modification, and a duplicate description will be omitted.

FIGS. 6 (a) to (e) correspond to the process of washing the shielding plate 63 explained in the second embodiment. A difference from the second embodiment is an addition of a process of washing a side surface portion in the periphery of the shielding plate 63 to the process illustrated in FIG. 6 (c).

As shown in FIG. 6 (c), the control unit 10b controls the first nozzle moving mechanism 53 to locate the first nozzle 52 above the periphery of the shielding plate 63 when the treatment liquid L is supplied to the surface (lower surface) of the shielding plate 63 that faces the substrate from the lower treatment liquid nozzle 48. Then, the treatment liquid L is supplied to the periphery of the shielding plate 63 from the first nozzle 52, and the side surface portion in the periphery of the shielding plate 63 is washed by the treatment liquid L.

As explained above, the third embodiment has the same advantageous effect as the second embodiment. Furthermore, not only the lower surface of the shielding plate 63, but also the side surface portion is washed by the treatment liquid L. If the droplets of each of the treatment liquids adhering to the shielding plate 63 remain, deposition of the droplets of each of the treatment liquids are precipitated and may fall onto the front surface of the substrate W. In the present embodiment, it is possible to prevent generation of such deposition of treatment liquids and IPA, etc. by washing the side surface portion of the shielding plate 63, thereby preventing the occurrence of defective products due to contamination, etc. of a substrate W.

In the present embodiment, the same first nozzle 52 is used for the washing treatment for the side surface portion of the shielding plate 63 as that used for the treatment of the front surface of a substrate W. Thus, upsizing of the substrate treating device 1 can be prevented even when the side surface portion of the shielding plate 63 is washed.

The third embodiment is performed after a preset number of sheets of substrates are treated. The first nozzle 52 is not only located above the periphery of the shielding plate 63 to supply the treatment liquid L, but is also made to swing to wash the upper surface of the shielding plate 63.

While certain embodiments have been described in the above, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the invention. The accompanying claims and their equivalents are intended to cover such forms or modifications as would fall within the scope and spirit of the invention.

For example, the first, second, and third embodiments may be combined. In this case, when the treatment of multiple substrates W is successively performed, the number of sheets of the substrate W (a preset number of sheets) for which each of the first, second, and third embodiments is performed is set in a storage of the control unit 10b in advance. Then, the control unit 10b performs the operation of each of the embodiments on the condition that the number of treated substrates W reaches the preset number. For example, the first embodiment is performed every time a substrate W is treated, the second embodiment is performed for 10 sheets, and the third embodiment is performed per lot. Not all of the three embodiments are necessarily combined; the first and second embodiments may be combined, or the first and third embodiments may be combined. The operation is not performed when a set number of sheets is zero.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

1. A substrate treating device that rotates and washes a substrate, the device comprising:
a spinning holding mechanism for holding a substrate;
a treatment liquid supply nozzle for supplying a treatment liquid to the substrate;
a shielding plate that is arranged opposite to the substrate held by the spinning holding mechanism and that moves in a contact/separate direction with respect to the substrate;
a shielding plate rotating mechanism for rotating the shielding plate; and
a control device for controlling the shielding plate rotating mechanism to locate the shielding plate at a standby position when the treatment liquid is not supplied and to rotate the shielding plate without moving the shielding plate from the standby position when the treatment liquid is supplied from the treatment liquid supply nozzle.

2. The substrate treating device according to claim 1, wherein
the shielding plate has a gas supply nozzle for supplying a gas to the substrate, and
a gas of such an amount that the treatment liquid does not adhere to a nozzle opening is exhausted from the gas supply nozzle during treatment of the substrate with the treatment liquid, the nozzle opening continuing to the gas supply nozzle and being provided on the shielding plate.

3. The substrate treating device according to claim 1, wherein
a rear surface nozzle head for supplying the treatment liquid and a gas respectively to a rear surface of the substrate is provided, and the treatment liquid and the gas are respectively supplied to the shielding plate by the rear surface nozzle head after the substrate is carried out from a treatment chamber.

4. The substrate treating device according to claim 1, wherein
the treatment liquid supply nozzle supplies the treatment liquid to a periphery of the shielding plate.

5. A substrate treating device comprising:
a spinning holding mechanism for holding a substrate;
a treatment liquid supply nozzle for supplying a treatment liquid to the substrate;
a shielding plate that is arranged opposite to the substrate held by the spinning holding mechanism and that moves in a contact/separate direction with respect to the substrate;
a shielding plate rotating mechanism for rotating the shielding plate; and
a rear surface nozzle head for respectively supplying the treatment liquid and a gas to a rear surface of the substrate; and
a control device,
wherein the control device:
controls, for every first number of sheets that is preset, the shielding plate rotating mechanism to locate the shielding plate at a standby position when the treatment liquid is not supplied and to rotate the shielding plate without moving the shielding plate from the standby position when the treatment liquid is supplied from the treatment liquid supply nozzle,
controls, for every second number of sheets that is preset, the rear surface nozzle head to respectively supply the treatment liquid and the gas to the shielding plate after the substrate is carried out from a treatment chamber, and
controls, for every third number of sheets that is preset, the treatment liquid supply nozzle to supply the treatment liquid to a periphery of the shielding plate after the substrate is carried out from the treatment chamber.

6. A substrate treating method for rotating and washing a substrate, the method comprising:
a substrate holding step of holding the substrate;
a treatment liquid supply step of supplying a treatment liquid to the substrate from a treatment liquid supply nozzle;
a shielding plate moving step of moving a shielding plate in a contact/separate direction with respect to the substrate, the shielding plate being arranged facing the substrate held in the substrate holding step; and
a shielding plate rotating step of locating the shielding plate at a standby position when the treatment liquid is not supplied and rotating the shielding plate without moving the shielding plate from the standby position during the supply of the treatment liquid by the treatment liquid supply nozzle.

7. The substrate treating method according to claim 6, wherein
a gas is supplied from the shielding plate in the treatment liquid supply step.

8. The substrate treating method according to claim 6, wherein the method includes a shielding plate washing step of respectively supplying the treatment liquid and a gas to the shielding plate after the substrate is carried out from a treatment chamber.

9. The substrate treating method according to claim 8, wherein
the treatment liquid is supplied to a periphery of the shielding plate in the shielding plate washing step.
